(19) United States
(12) Patent Application Publication
(10) Pub. No.: US 2025/0011921 A1
(43) Pub. Date: Jan. 9, 2025

(54) DEVICE AND METHOD FOR MANUFACTURING DISPLAY APPARATUS

(71) Applicant: Samsung Display Co., LTD., Yongin-si (KR)

(72) Inventors: Junggon KIM, Yongin-si (KR); Choelmin JANG, Yongin-si (KR)

(21) Appl. No.: 18/896,073

(22) Filed: Sep. 25, 2024

(30) Foreign Application Priority Data
Feb. 14, 2014 (KR) 10-2024-0020901

(51) Int. Cl. C23C 16/04; C23C 16/458; H01L 25/075; H01L 33/00

(52) U.S. Cl. CPC C23C 16/042; C23C 16/4583; H01L 33/0095; H01L 25/0753; H01L 2933/005

(57) ABSTRACT

A device for manufacturing a display apparatus includes a chamber including a first zone, a second zone, and a third zone arranged along a linear path, an inorganic film deposition mask disposed in the first zone, an organic film deposition mask disposed in the second zone, a deposition unit disposed in the third zone, and a susceptor which reciprocates between the first zone, the second zone, and the third zone.

This application claims priority to Korean Patent Application No. 10-2024-0020901, filed on Feb. 14, 2024, and all the benefits accruing therefrom under 35 U.S.C. § 119, the content of which in its entirety is herein incorporated by reference.

### BACKGROUND

### 1. Field

Embodiments relate to a device and method for manufacturing a display apparatus, where the display apparatus may include a light-emitting diode.

### 2. Description of the Related Art

Display apparatuses display data visually. Display apparatuses may provide images by light-emitting diodes. The uses and structures of display apparatuses are diversified, structures that are bendable from flat states to have certain angles are developed, and various designs are attempted to improve the quality of display apparatuses.

A display apparatus may include a plurality of pixels in the form of a pattern to implement an image. In this case, multiple layers including an emission layer may be included in the plurality of pixels in the form of a pattern. Such layers may be arranged on a substrate in different patterns depending on the types of the layers.

### SUMMARY

A thin-film encapsulation layer may be disposed on multiple layers disposed on a substrate of a display apparatus. The thin-film encapsulation layer may protect the multiple layers of the display apparatus and may prevent penetration of dust, moisture, or the like thereinto. The thin-film encapsulation layer may have a multilayer structure including an inorganic film including an inorganic material and an organic film including an organic material. The organic film or the inorganic film of the thin-film encapsulation layer may be formed by depositing the organic material or the inorganic material on the substrate in a chamber. In this case, after forming the inorganic film, it may be desired to take the substrate out of an inorganic film deposition chamber and insert the substrate into an organic film deposition chamber to form the organic film.

Additional features will be set forth in part in the description which follows and, in part, will be apparent from the description, or may be learned by practice of the presented embodiments of the disclosure.

In an embodiment of the disclosure, a device for manufacturing a display apparatus includes a chamber including a first zone, a second zone, and a third zone arranged along a linear path, an inorganic film deposition mask disposed in the first zone, an organic film deposition mask disposed in the second zone, a deposition unit disposed in the third zone, and a susceptor which reciprocates between the first zone, the second zone, and the third zone.

In an embodiment, the third zone may be disposed between the first zone and the second zone.

In an embodiment, the device may further include a first alignment unit disposed in the first zone, and a second alignment unit disposed in the second zone.

In an embodiment, at least one of the first alignment unit and the second alignment unit may include a mask moving portion which raises and lowers a mask, and a substrate moving portion which raises and lowers a substrate.

In an embodiment, the mask moving portion and the substrate moving portion may be extended and shortened in a predetermined direction.

In an embodiment, the device may further include a first mask holding unit which is disposed in the first zone and faces the first alignment unit, and a second mask holding unit which is disposed in the second zone and faces the second alignment unit.

In an embodiment, at least one of the first mask holding unit and the second mask holding unit may include a plurality of mask holders which bend and rotate.

In an embodiment, the deposition unit and at least one of the first mask holding unit and the second mask holding unit may be disposed on a same surface of the chamber.

In an embodiment, a first opening may be defined in the inorganic film deposition mask, a second opening may be defined in defined in the organic film deposition mask, and the first opening and the second opening may respectively have sizes different from each other.

In an embodiment, the device may further include a buffer plate attached to at least one of opposite sides of the susceptor.

In an embodiment of the disclosure, a method of manufacturing a display apparatus includes combining a substrate and an inorganic film deposition mask with each other on a susceptor in a first zone of a chamber, depositing a first inorganic film on the substrate by a deposition unit and the inorganic film deposition mask in a third zone of the chamber, combining the substrate and an organic film deposition mask with each other on the susceptor in a second zone of the chamber, and depositing an organic film on the first inorganic film by the deposition unit and the organic film deposition mask in the third zone of the chamber.

In an embodiment, the combining the substrate and the inorganic film deposition mask may include at least one of bringing the inorganic film deposition mask into proximity with the substrate, and aligning the substrate and the inorganic film deposition mask with each other.

In an embodiment, the combining the substrate and the organic film deposition mask may include at least one of bringing the organic film deposition mask into proximity with the substrate, and aligning the substrate and the organic film deposition mask with each other.

In an embodiment, the method may further include at least one of moving the susceptor, the substrate, and the inorganic film deposition mask from the first zone to the third zone as one body, and moving the susceptor, the substrate, and the organic film deposition mask from the second zone to the third zone as one body.

In an embodiment, the method may further include at least one of separating the inorganic film deposition mask from the substrate, and separating the organic film deposition mask from the substrate.

In an embodiment, the method may further include at least one of holding the inorganic film deposition mask on a first mask holding unit provided on one surface of the chamber, and holding the organic film deposition mask on a second mask holding unit provided on the one surface of the chamber.

In an embodiment, the deposition unit and at least one of the first mask holding unit and the second mask holding unit may be arranged on a same surface of the chamber.

In an embodiment, the method may further include recombining the substrate and the inorganic film deposition mask with each other on the susceptor in the first zone of the chamber, and depositing a second inorganic film on the organic film by the deposition unit and the inorganic film deposition mask in the third zone of the chamber.

In an embodiment, the method may further include inserting the substrate into the chamber.

In an embodiment, the third zone may be disposed between the first zone and the second zone.

### BRIEF DESCRIPTION OF THE DRAWINGS

The above and other features and advantages of illustrative embodiments of the disclosure will be more apparent from the following description taken in conjunction with the accompanying drawings, in which:

FIG. 1 is a cross-sectional view of an embodiment of a device for manufacturing a display apparatus;

FIGS. 2A and 2B are plan views of an embodiment of a device for manufacturing a display apparatus;

FIGS. 3A and 3B are plan views of an embodiment of a device for manufacturing a display apparatus;

FIGS. 4A and 4B are plan views of an embodiment of first and second deposition masks and first and second mask holding units;

FIG. 5 is a cross-sectional view of the first mask holding unit, taken along line V-V′ of FIG. 4A;

FIGS. 6A, 6B, 6C, 6D, 6E, 6F, 6G, 6H, 6I, 6J, 6K, 6L, and 6M are cross-sectional views of an embodiment of processes of a method of manufacturing a display apparatus;

FIG. 7 is a plan view of an embodiment of a display apparatus manufactured by a device for manufacturing a display apparatus; and

FIG. 8 is a cross-sectional view of an embodiment of a portion of a display apparatus manufactured by a device for manufacturing a display apparatus.

### DETAILED DESCRIPTION

Reference will now be made in detail to embodiments, illustrative embodiments of which are illustrated in the accompanying drawings, where like reference numerals refer to like elements throughout. In this regard, the illustrated embodiments may have different forms and should not be construed as being limited to the descriptions set forth herein. Accordingly, the embodiments are merely described below, by referring to the drawing figures, to explain features of the description. As used herein, the term “and/or” includes any and all combinations of one or more of the associated listed items. Throughout the disclosure, the expression “at least one of a, b or c” indicates only a, only b, only c, both a and b, both a and c, both b and c, all of a, b, and c, or variations thereof.

As the disclosure allows for various changes and numerous embodiments, particular embodiments will be illustrated in the drawings and described in detail in the written description. Effects and features of the disclosure and methods of achieving the same will be apparent with reference to embodiments and drawings described below in detail. The disclosure may, however, be embodied in many different forms and should not be construed as being limited to the embodiments set forth herein.

Hereinafter, embodiments of the disclosure will be described in detail with reference to the accompanying drawings, and in the description with reference to the drawings, the same or corresponding elements are indicated by the same reference numerals and redundant descriptions thereof are omitted.

In the following embodiments, while terms such as “first” and “second” are used to describe various elements, these elements are not limited by these terms. These terms are only used to distinguish one element from another element.

In the following embodiments, an expression used in the singular encompasses the expression of the plural, unless it has a clearly different meaning in the context.

In the following embodiments, terms such as “comprise,” “include,” and “have” are used to specify the presence of stated features or elements, but do not preclude the addition of one or more other features or elements.

In the following embodiments, when a layer, region, or element is referred to as being “on” another layer, region, or element, it may be directly or indirectly on the other layer, region, or element. That is, for example, intervening layers, regions, or elements may be present.

Sizes of elements in the drawings may be exaggerated for convenience of description. For example, sizes and thicknesses of elements in the drawings are arbitrarily illustrated for convenience of description, and the following the disclosure is not limited thereto.

When an embodiment may be implemented differently, a process order may be performed differently from the described order. For example, two consecutively described processes may be performed substantially at the same time or may be performed in an order opposite to the described order.

As used herein, the expression “A and/or B” represents A, B, or A and B. In addition, the expression “at least one of A and B” represents A, B, or A and B.

An x-axis, a y-axis, and a z-axis are not limited to three axes of a rectangular coordinate system and may be interpreted in a broader sense. For example, the x-axis, the y-axis, and the z-axis may be perpendicular to one another or may represent different directions that are not perpendicular to one another.

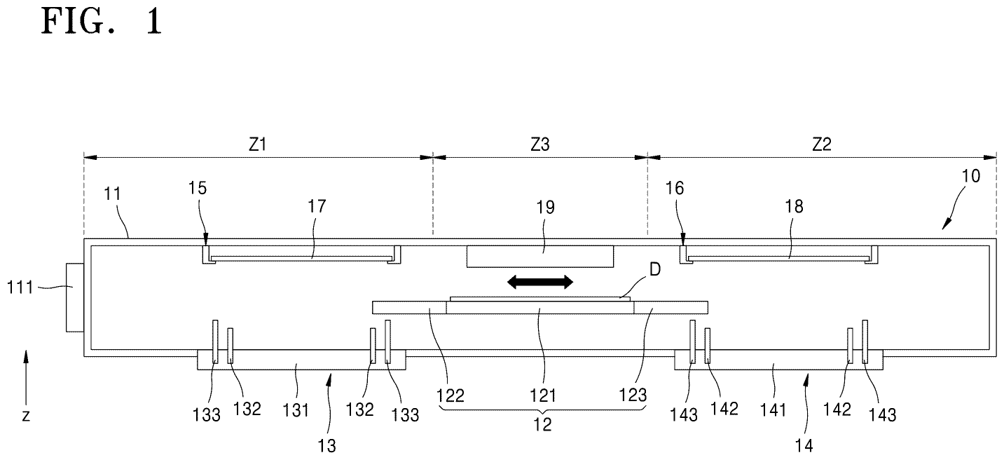

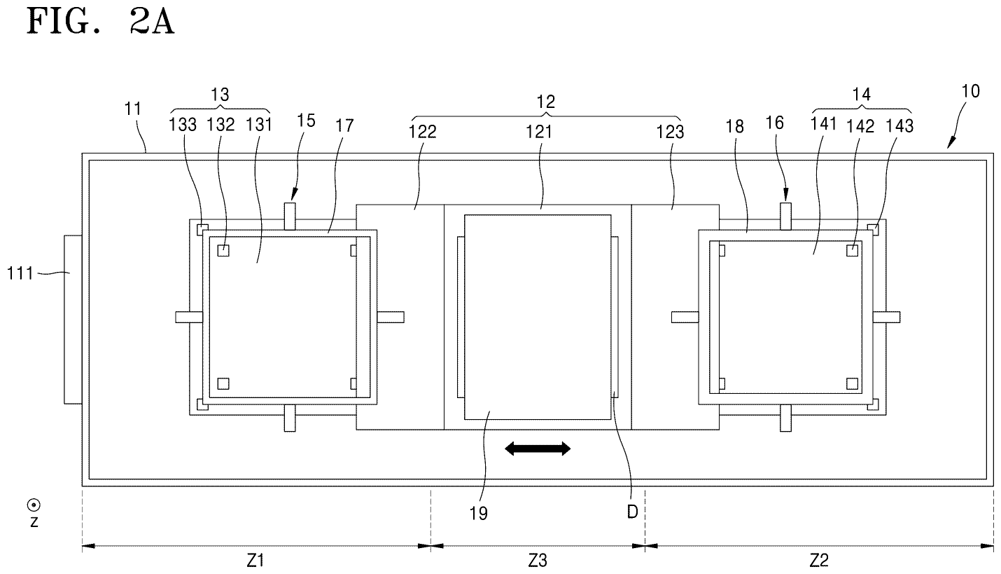

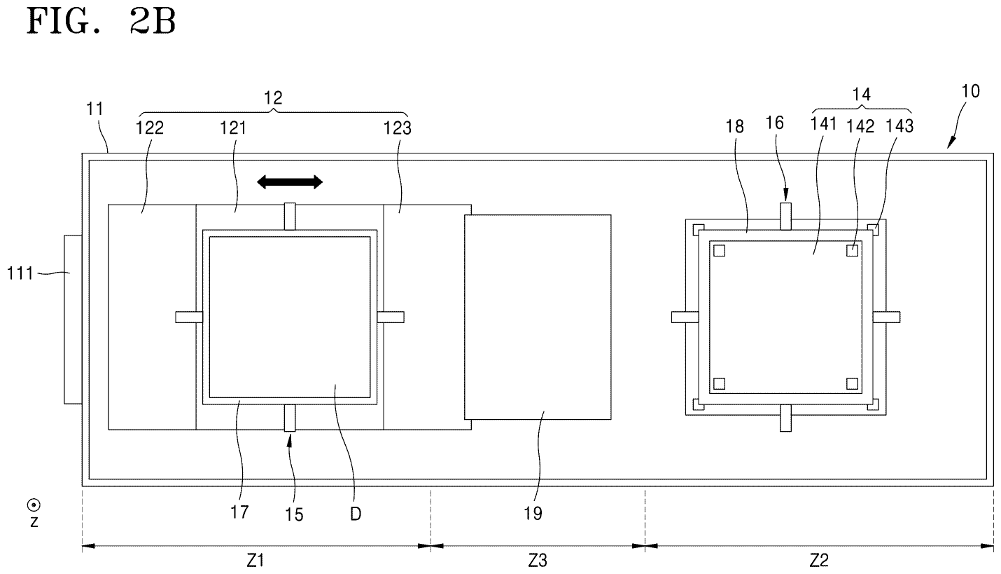

FIG. 1 is a cross-sectional view of an embodiment of a device 10 for manufacturing a display apparatus. FIGS. 2A and 2B are plan views of an embodiment of the device 10 for manufacturing a display apparatus. FIGS. 2A and 2B show the same device 10 for manufacturing a display apparatus, but respectively show states in which a moving unit 12 has moved to different positions.

Referring to FIGS. 1, 2A, and 2B, the device 10 for manufacturing a display apparatus may include a chamber 11, the moving unit 12, a first alignment unit 13, a second alignment unit 14, a first mask holding unit 15, a second mask holding unit 16, a first deposition mask 17, a second deposition mask 18, and a deposition unit 19.

The chamber 11 may have a space defined therein, and a portion of the chamber 11 may be opened. A gate valve 111 may be installed in the opened portion of the chamber 11. The opened portion of the chamber 11 may be opened or closed according to an operation of the gate valve 111. In FIG. 1, a side (hereinafter, a left side) of the chamber 11 which is adjacent to the first alignment unit 13 is opened, and the gate valve 111 is installed on the opened side, but the disclosure is not limited thereto. In another embodiment, a side (hereinafter, a right side) of the chamber 11 which is adjacent to the second alignment unit 14 may be opened, and the gate valve 111 may be installed on the opened side. A display substrate D may be inserted into the chamber 11 or taken out of the chamber 11 through the gate valve 111 or the opened portion of the chamber 11.

The chamber 11 may include a first zone Z1, a second zone Z2, and a third zone Z3. In an embodiment, the third zone Z3 may be disposed between the first zone Z1 and the second zone Z2.

The moving unit 12 may be disposed in the chamber 11 and may make a translational movement in the chamber 11. The moving unit 12 may move to the left or right in the chamber 11 and may move freely between the first zone Z1, the second zone Z2, and the third zone Z3. In an embodiment, FIG. 2B shows a state in which the moving unit 12 has moved to the left so that the moving unit 12 is disposed relatively on the left, compared to the state in FIG. 2A, for example. In an embodiment, the device 10 for manufacturing a display apparatus may include an element capable of moving the moving unit 12, such as a robot arm (not shown) or a moving rail (not shown).

The moving unit 12 may include a susceptor 121, a first buffer plate 122, and a second buffer plate 123. The susceptor 121 may provide a space in which the display substrate D may be disposed and may support the display substrate D. In other words, the display substrate D may be disposed on the susceptor 121. In an embodiment, the susceptor 121 may support and heat the display substrate D at the same time. To this end, the susceptor 121 may include a heating element therein.

The first and second buffer plates 122 and 123 may be respectively arranged on opposite sides of the susceptor 121. In an embodiment, the first and second buffer plates 122 and 123 may be coupled to the susceptor 121. In an embodiment, the susceptor 121, the first buffer plate 122, and the second buffer plate 123 may move as one body when the moving unit 12 moves. In an embodiment, the first and second buffer plates 122 and 123 may be substantially the same as each other and may be symmetrically arranged about the susceptor 121. In an embodiment, the first buffer plate 122 may be disposed to the left side of the susceptor 121, and the second buffer plate 123 may be disposed to the right side of the susceptor 121. In another embodiment, the first buffer plate 122 may be disposed to the right side of the susceptor 121, and the second buffer plate 123 may be disposed to the left side of the susceptor 121. The first and second buffer plates 122 and 123 may prevent or reduce a deposition material facing the outside of the display substrate D, among deposition materials sprayed during a deposition process, from reaching another element, e.g., the first alignment unit 13 or the second alignment unit 14, disposed below the moving unit 12. In an embodiment, referring to FIGS. 2A, it may be seen that, when the display substrate D and the susceptor 121 overlap the deposition unit 19, the first buffer plate 122 covers a portion of the first alignment unit 13 and the second buffer plate 123 covers a portion of the second alignment unit 14, for example.

The first alignment unit 13 may be disposed in the first zone Z1 of the chamber 11. The first alignment unit 13 may be disposed on one surface of the chamber 11, e.g., a lower surface of the chamber 11. In an embodiment, as shown in FIG. 1, a portion of the first alignment unit 13 may protrude to the outside of the chamber 11, and an upper surface of the first alignment unit 13 may be disposed on the same plane as that of an inner surface of the chamber 11. In an embodiment, a portion of the first alignment unit 13 may protrude into the inside of the chamber 11. In another embodiment, the first alignment unit 13 may be entirely disposed in the chamber 11.

The first alignment unit 13 may include a first aligner 131, a first substrate moving portion 132, and a first mask moving portion 133. The first aligner 131 of the first alignment unit 13 may be fixed in the chamber 11. The first substrate moving portion 132 may rise and fall and may be combined with the display substrate D. In an embodiment, the first substrate moving portion 132 may be extended and shortened. In an embodiment, the first substrate moving portion 132 may include any suitable linear actuator. The first mask moving portion 133 may rise and fall and may be combined with the first deposition mask 17. In an embodiment, the first mask moving portion 133 may be extended and shortened. In an embodiment, the first mask moving portion 133 may include any suitable linear actuator.

The first mask moving portion 133 and the first substrate moving portion 132 may be coupled to the first aligner 131. In an embodiment, a plurality of first mask moving portions 133 may be provided and may be arranged adjacent to respective corners of the first aligner 131. In an embodiment, a plurality of first substrate moving portions 132 may be provided and may be arranged relatively far from respective corners of the first aligner 131, compared to the first mask moving portion 133. In other words, the first substrate moving portion 132 may be disposed relatively close to the center of the first aligner 131, compared to the first mask moving portion 133. In other words, the first mask moving portion 133 may be disposed between a corner of the first aligner 131 and the first substrate moving portion 132. In another embodiment, a plurality of first mask moving portions 133 and a plurality of first substrate moving portions 132 may be provided and may be arranged adjacent to respective edges (or corners) of the first aligner 131.

The first alignment unit 13 may align the display substrate D and the first deposition mask 17 with each other. To this end, the first aligner 131 of the first alignment unit 13 may include a vision portion (not shown) that recognizes an alignment mark provided on the display substrate D and/or the first deposition mask 17. In an embodiment, after the first substrate moving portion 132 is combined with the display substrate D and the first mask moving portion 133 is combined with the first deposition mask 17, the vision portion (not shown) of the first aligner 131 may photograph an alignment mark of the display substrate D and an alignment mark of the first deposition mask 17. Thereafter, the first substrate moving portion 132 may move the display substrate D and the first mask moving portion 133 may move the first deposition mask 17, so that the alignment mark of the display substrate D and the alignment mark of the first deposition mask 17 are aligned with each other. In an embodiment, the first substrate moving portion 132 may include any suitable element capable of moving the display substrate D or moving together with the display substrate D. In an embodiment, the first mask moving portion 133 may include any suitable element capable of moving the first deposition mask 17 or moving together with the first deposition mask 17.

The second alignment unit 14 may be disposed in the second zone Z2 of the chamber 11. The second alignment unit 14 may be disposed on one surface of the chamber 11, e.g., the lower surface of the chamber 11. In an embodiment, as shown in FIG. 1, a portion of the second alignment unit 14 may protrude to the outside of the chamber 11, and an upper surface of the second alignment unit 14 may be disposed on the same plane as that of the inner surface of the chamber 11. In an embodiment, a portion of the second alignment unit 14 may protrude into the inside of the chamber 11. In another embodiment, the second alignment unit 14 may be entirely disposed in the chamber 11.

The second alignment unit 14 may include a second aligner 141, a second substrate moving portion 142, and a second mask moving portion 143. The second aligner 141 of the second alignment unit 14 may be fixed in the chamber 11. The second substrate moving portion 142 may rise and fall and may be combined with the display substrate D. In an embodiment, the second substrate moving portion 142 may be extended and shortened. In an embodiment, the second substrate moving portion 142 may include any suitable linear actuator. The second mask moving portion 143 may rise and fall and may be combined with the second deposition mask 18. In an embodiment, the second mask moving portion 143 may be extended and shortened. In an embodiment, the second mask moving portion 143 may include any suitable linear actuator.

The second mask moving portion 143 and the second substrate moving portion 142 may be coupled to the second aligner 141. In an embodiment, a plurality of second mask moving portions 143 may be provided and may be arranged adjacent to respective corners of the second aligner 141. In an embodiment, a plurality of second substrate moving portions 142 may be provided and may be arranged relatively far from respective corners of the second aligner 141, compared to the second mask moving portion 143. In other words, the second substrate moving portion 142 may be disposed relatively close to the center of the second aligner 141, compared to the second mask moving portion 143. In other words, the second mask moving portion 143 may be disposed between a corner of the second aligner 141 and the second substrate moving portion 142. In another embodiment, a plurality of second mask moving portions 143 and a plurality of second substrate moving portions 142 may be provided and may be arranged adjacent to respective edges (or corners) of the second aligner 141.

The second alignment unit 14 may align the display substrate D and the second deposition mask 18 with each other. To this end, the second aligner 141 of the second alignment unit 14 may include a vision portion (not shown) that recognizes an alignment mark provided on the display substrate D and/or the second deposition mask 18. In an embodiment, after the second substrate moving portion 142 is combined with the display substrate D and the second mask moving portion 143 is combined with the second deposition mask 18, the vision portion (not shown) of the second aligner 141 may photograph an alignment mark of the display substrate D and an alignment mark of the second deposition mask 18. Thereafter, the second substrate moving portion 142 may move the display substrate D and the second mask moving portion 143 may move the second deposition mask 18, so that the alignment mark of the display substrate D and the alignment mark of the second deposition mask 18 are aligned with each other. In an embodiment, the second substrate moving portion 142 may include any suitable element capable of moving the display substrate D or moving together with the display substrate D. In an embodiment, the second mask moving portion 143 may include any suitable element capable of moving the second deposition mask 18 or moving together with the second deposition mask 18.

The first mask holding unit 15 may be disposed in the first zone Z1 of the chamber 11. The first mask holding unit 15 may be disposed to face the first alignment unit 13. In an embodiment, the first mask holding unit 15 may be disposed on one surface of the chamber 11 which is opposite to the surface of the chamber 11 on which the first alignment unit 13 is disposed. In an embodiment, the first alignment unit 13 may be disposed on a lower surface of the internal space of the chamber 11, and the first mask holding unit 15 may be disposed on an upper surface of the internal space of the chamber 11 to face the first alignment unit 13, for example. Accordingly, in a plane view, at least a portion of the first mask holding unit 15 may overlap the first alignment unit 13. The first mask holding unit 15 may be combined with the first deposition mask 17 to hold the first deposition mask 17 in a predetermined position. In an embodiment, the first mask holding unit 15 may hold the first deposition mask 17 so that the first deposition mask 17 is disposed above (or in a +z direction relative to) the moving unit 12 and the display substrate D, for example.

The second mask holding unit 16 may be disposed in the second zone Z2 of the chamber 11. The second mask holding unit 16 may be disposed to face the second alignment unit 14. In an embodiment, the second mask holding unit 16 may be disposed on one surface of the chamber 11 which is opposite to the surface of the chamber 11 on which the second alignment unit 14 is disposed. In an embodiment, the second alignment unit 14 may be disposed on the lower surface of the internal space of the chamber 11, and the second mask holding unit 16 may be disposed on the upper surface of the internal space of the chamber 11 to face the second alignment unit 14, for example. Accordingly, in a plane view, at least a portion of the second mask holding unit 16 may overlap the second alignment unit 14. The second mask holding unit 16 may be combined with the second deposition mask 18 to hold the second deposition mask 18 in a predetermined position. In an embodiment, the second mask holding unit 16 may hold the second deposition mask 18 so that the second deposition mask 18 is disposed above (or in the +z direction relative to) the moving unit 12 and the display substrate D, for example.

The first deposition mask 17 may be disposed in the first zone Z1. The first deposition mask 17 may be disposed in the third zone Z3 during a deposition process. The first deposition mask 17 may overlap the first alignment unit 13, e.g., the first mask moving portion 133. The first deposition mask 17 may be held by the first mask holding unit 15. The first deposition mask 17 may be moved to various positions in the chamber 11, in addition to the position in which the first deposition mask 17 is held by the first mask holding unit 15. In an embodiment, the first deposition mask 17 may be an inorganic film deposition mask. In an embodiment, a central portion of the first deposition mask 17 may be opened.

The second deposition mask 18 may be disposed in the second zone Z2. The second deposition mask 18 may be disposed in the third zone Z3 during a deposition process. The second deposition mask 18 may overlap the second alignment unit 14, e.g., the second mask moving portion 143. The second deposition mask 18 may be held by the second mask holding unit 16. The second deposition mask 18 may be moved to various positions in the chamber 11, in addition to the position in which the second deposition mask 18 is held by the second mask holding unit 16. In an embodiment, the second deposition mask 18 may be an inorganic film deposition mask. In an embodiment, a central portion of the second deposition mask 18 may be opened.

The deposition unit 19 may be disposed in the third zone Z3 of the chamber 11. In an embodiment, the deposition unit 19 may be disposed between the first mask holding unit 15 and the second mask holding unit 16. The deposition unit 19 may be disposed on one surface of the chamber 11. In an embodiment, the deposition unit 19 may be disposed on the upper surface of the internal space of the chamber 11. In an embodiment, the deposition unit 19, the first mask holding unit 15, and the second mask holding unit 16 may be arranged on the same inner surface of chamber 11, for example. The deposition unit 19 may store a deposition material therein or may receive a deposition material from the outside. In an embodiment, the deposition unit 19 may apply heat to the deposition material to vaporize or sublimate the deposition material. In an embodiment, the deposition unit 19 may be used for both deposition of an inorganic deposition material and deposition of an organic deposition material.

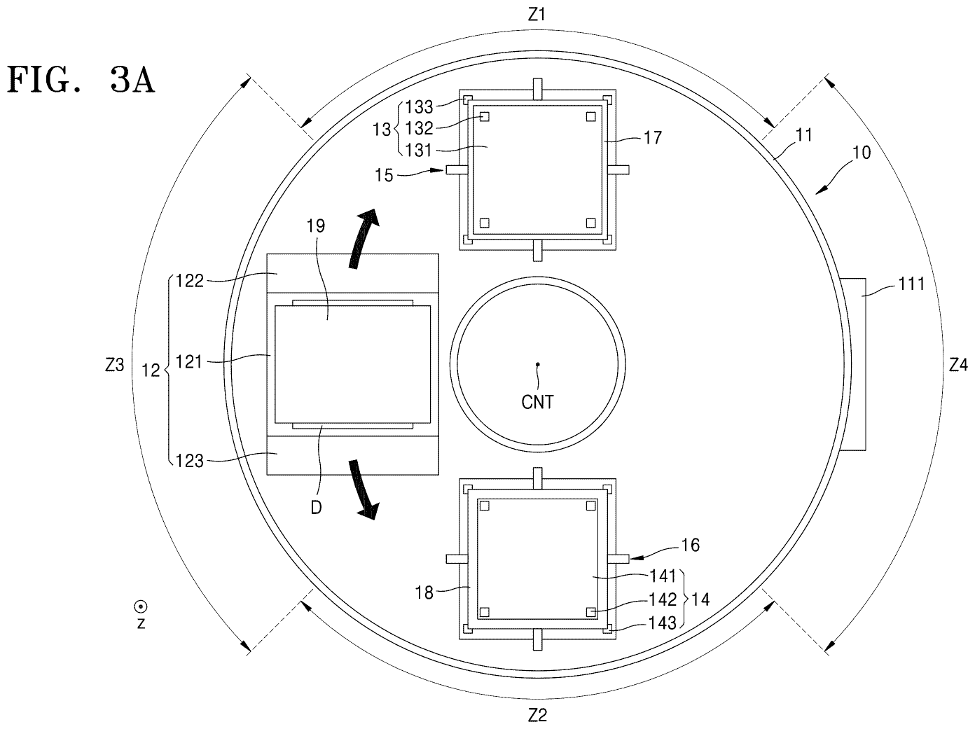

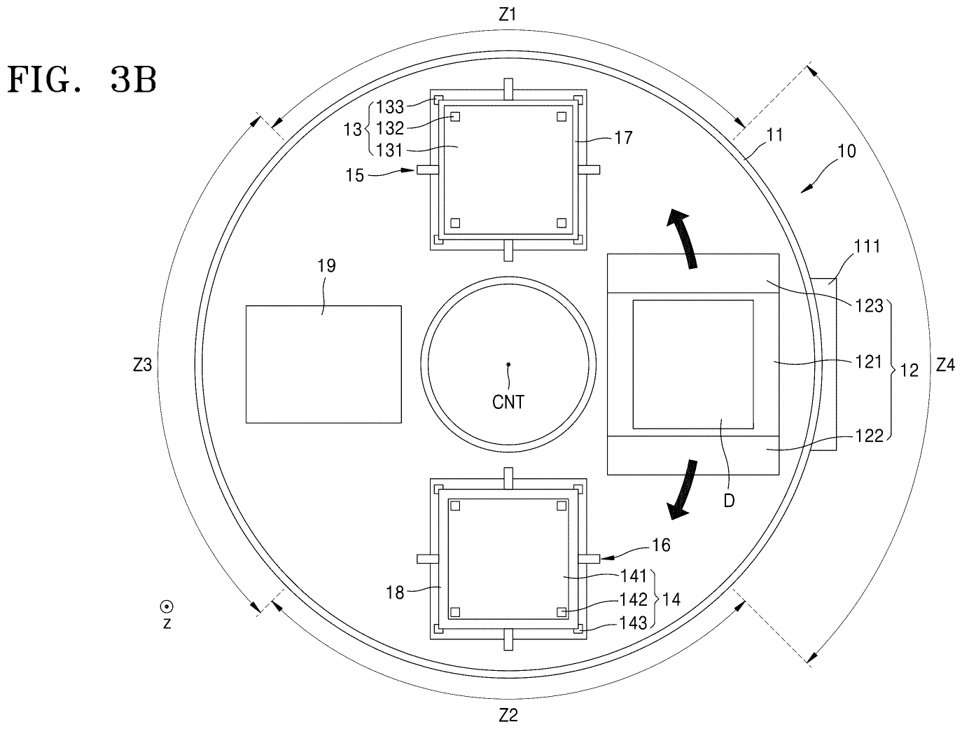

FIGS. 3A and 3B are plan views of an embodiment of the device 10 for manufacturing a display apparatus. FIGS. 3A and 3B show the same device 10 for manufacturing a display apparatus, but respectively show states in which the moving unit 12 has moved to different positions.

While other features of the illustrated embodiment are the same as those of the embodiment described above with reference to FIGS. 1, 2A, and 2B, there may be differences in terms of the shape of the chamber 11 and the arrangement of each element. Hereinafter, such differences are mainly described.

Referring to FIGS. 3A and 3B, the chamber 11 of the device 10 for manufacturing a display apparatus may have a substantially donut shape extending along a circular trajectory. In an embodiment, the internal space of the chamber 11, which is defined by a wall of the chamber 11, may be a donut-shaped space defined by rotating about one rotational axis CNT, and an external space of the chamber 11 may be disposed around the rotational axis CNT, for example. In another embodiment, the internal space of the chamber 11 may be a circular space defined by rotating about one axis, and the rotational axis CNT may also be disposed in the internal space of the chamber 11.

The chamber 11 may include the first zone Z1, the second zone Z2, the third zone Z3, and a fourth zone Z4. In an embodiment, the first zone Z1 may be disposed in a portion of the chamber 11 in an approximately twelve o'clock direction, the fourth zone Z4 may be disposed in a portion of the chamber 11 in an approximately three o'clock direction, the second zone Z2 may be disposed in a portion of the chamber 11 in an approximately six o'clock direction, and the third zone Z3 may be disposed in a portion of the chamber 11 in an approximately nine o'clock direction. In other words, the first zone Z1 may be disposed in a portion of the chamber 11 in an approximately twelve o'clock direction, and the fourth zone Z4, the second zone Z2, and the third zone Z3 may be located sequentially in a clockwise direction. In an embodiment, the chamber 11 may have a circular structure that may move in a clockwise or counterclockwise direction in one of the zones and return to the starting point. In an embodiment, the areas of the first to fourth zones Z1, Z2, Z3, and Z4 may be substantially the same.

A portion of the chamber 11 may be opened, and the gate valve 111 may be installed in the opened portion. In an embodiment, the opened portion of the chamber 11 and the gate valve 111 may be located in the fourth zone Z4. In an embodiment, the display substrate D may be inserted into the chamber 11 or taken out of the chamber 11 through the opened portion of the chamber 11 or the gate valve 111. Accordingly, in the illustrated embodiment, the display substrate D may be understood as being inserted into the chamber 11 or taken out of the chamber 11 in the fourth zone Z4.

The first alignment unit 13 and the first mask holding unit 15 may be arranged in the first zone Z1. Accordingly, in an embodiment, the first alignment unit 13 and the first mask holding unit 15 may be understood as being arranged in the portion of the chamber 11 in the approximately twelve o'clock direction. The second alignment unit 14 and the second mask holding unit 16 may be arranged in the second zone Z2. Accordingly, in an embodiment, the second alignment unit 14 and the second mask holding unit 16 may be understood as being arranged in the portion of the chamber 11 in the approximately six o'clock direction. The deposition unit 19 may be disposed in the third zone Z3. Accordingly, in an embodiment, the deposition unit 19 may be understood as being disposed in the portion of the chamber 11 in the approximately nine o'clock direction.

The moving unit 12 may move in the chamber 11. In an embodiment, the moving unit 12 may move along a circular trajectory having a constant radius about the rotational axis CNT. Accordingly, the moving unit 12 may freely move between the first to fourth zones Z1, Z2, Z3, and Z4. FIG. 3A shows a case in which the moving unit 12 is disposed in the third zone Z3, and FIG. 3B shows a case in which the moving unit 12 is disposed in the fourth zone Z4.

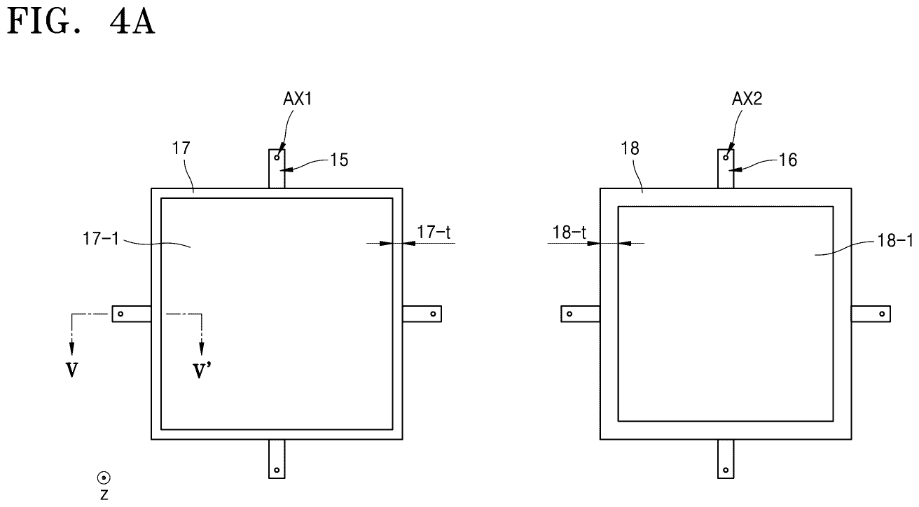

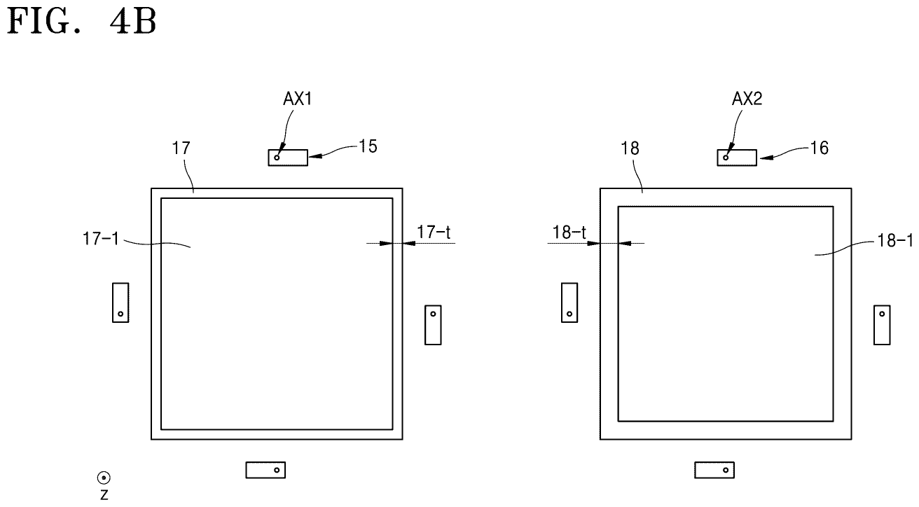

FIGS. 4A and 4B are plan views of an embodiment of the first and second deposition masks 17 and 18 and the first and second mask holding units 15 and 16. FIGS. 4A and 4B show states in which the same first and second mask holding units 15 and 16 are in different positions.

Referring to FIG. 4A, a central portion of each of the first deposition mask 17 and the second deposition mask 18 may be opened. In an embodiment, a first opening 17-1 may be defined in the first deposition mask 17, and a second opening 18-1 may be defined in the second deposition mask 18, for example. In an embodiment, the overall sizes of the first deposition mask 17 and the second deposition mask 18, respectively, may be substantially the same as each other, and the sizes of the first opening 17-1 and the second opening 18-1, respectively, may be different from each other. In other words, the overall sizes of the first deposition mask 17 and the second deposition mask 18, respectively, may be substantially the same as each other, and a width 17-t of the first deposition mask 17 and a width 18-t of the second deposition mask 18 may be different from each other. In an embodiment, the width 17-t of the first deposition mask 17 may be less than the width 18-t of the second deposition mask 18, and the first opening 17-1 of the first deposition mask 17 may be greater than the second opening 18-1 of the second deposition mask 18. Accordingly, the first deposition mask 17 and the second deposition mask 18 may be used to deposit layers having different areas.

The first mask holding unit 15 may be disposed in a-z direction relative to the first deposition mask 17 and may support and hold the first deposition mask 17. The first mask holding unit 15 may include a plurality of sections. In an embodiment, the sections may be disposed to overlap respective edges of the first deposition mask 17. In an embodiment, respective sections of the first mask holding unit 15 may be arranged in approximately twelve o'clock, three o'clock, six o'clock, and nine o'clock directions of the first deposition mask 17, for example. A portion of each section of the first mask holding unit 15 may overlap the first deposition mask 17.

The second mask holding unit 16 may be disposed in the −z direction relative to the second deposition mask 18 and may support and hold the second deposition mask 18. The second mask holding unit 16 may include a plurality of sections. In an embodiment, the sections may be arranged to overlap respective edges of the second deposition mask 18. In an embodiment, respective sections of the second mask holding unit 16 may be arranged in approximately twelve o'clock, three o'clock, six o'clock, and nine o'clock directions of the second deposition mask 18, for example. A portion of each section of the second mask holding unit 16 may overlap the second deposition mask 18.

In an embodiment, each section of the first mask holding unit 15 may rotate about a first axis AX1 provided therein. In an embodiment, each section of the second mask holding unit 16 may rotate about a second axis AX2 provided therein. Referring to FIGS. 4A and 4B together, each section of the first mask holding unit 15 may rotate at a predetermined angle (e.g., 90 degrees) about the first axis AX1. Similarly, each section of the second mask holding unit 16 may rotate at a predetermined angle (e.g., 90 degrees) about the second axis AX2. Each section of each of the first and second mask holding units 15 and 16 may rotate from the state shown in FIG. 4A to the state shown in FIG. 4B, e.g., in a counterclockwise direction, and may release the first deposition mask 17 or the second deposition mask 18 supported and held by the section. In addition, each section of each of the first and second mask holding units 15 and 16 may rotate from the state shown in FIG. 4B to the state shown in FIG. 4A, e.g., in a clockwise direction, and may support and hold the first deposition mask 17 or the second deposition mask 18 that has been released. However, the disclosure is not limited to such predetermined directions of rotation. In another embodiment, each section of each of the first and second mask holding units 15 and 16 may rotate in the clockwise direction when releasing the first deposition mask 17 or the second deposition mask 18. Similarly, each section of each of the first and second mask holding units 15 and 16 may rotate in the counterclockwise direction when supporting and holding the first deposition mask 17 or the second deposition mask 18.

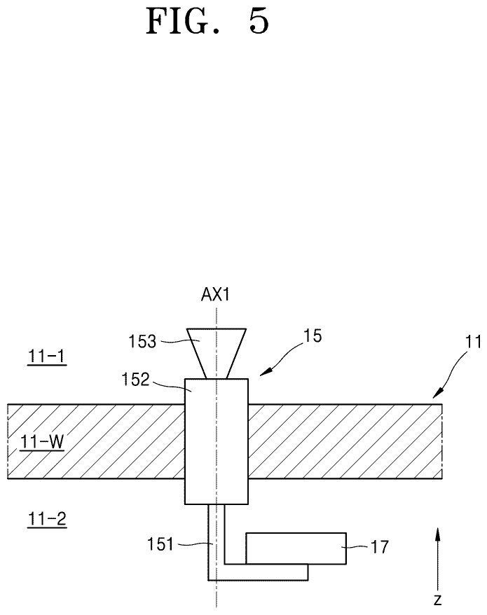

FIG. 5 is a cross-sectional view of the first mask holding unit 15, taken along line V-V′ of FIG. 4A. Hereinafter, while descriptions are made based on one of multiple sections of the first mask holding unit 15, features described below may be equally applied to the other sections of the first mask holding unit 15 and further to the second mask holding unit 16 and sections thereof.

Referring to FIG. 5, one section of the first mask holding unit 15 may include a mask holder 151, a sealing portion 152, and a rotational portion 153.

An exterior 11-1 and an interior 11-2 of the chamber 11 may be separated from each other by a wall 11-W of the chamber 11. The mask holder 151 may be disposed in the interior 11-2 of the chamber 11 and may be in direct contact with the first deposition mask 17 and support the first deposition mask 17. The mask holder 151 may be connected to the sealing portion 152. The sealing portion 152 may be fixed to the wall 11-W of the chamber 11 and may penetrate the wall 11-W of the chamber 11. The sealing portion 152 may tightly seal the exterior 11-1 and the interior 11-2 of the chamber 11 to prevent fluid communication therebetween. The rotational portion 153 may be disposed in the exterior 11-1 of the chamber 11 and may be connected to the sealing portion 152.

The rotational portion 153 may include any element capable of generating rotation. In an embodiment, the rotational portion 153 may include a member such as a pneumatic rotational cylinder or a rotational actuator to generate a rotational motion about a predetermined axis, for example. In an embodiment, the rotational portion 153 may generate a rotational motion about the first axis AX1. The sealing portion 152 may include any element capable of transmitting the rotational motion generated by the rotational portion 153 to the mask holder 151. In an embodiment, the sealing portion 152 may include a magnetic fluid seal or the like to transmit the rotational motion generated by the rotational portion 153 connected to one side of the sealing portion 152 to the mask holder 151 connected to an opposite side of the sealing portion 152, for example. As a result, the sealing portion 152 may seal the interior 11-2 of the chamber 11 and, at the same time, may transmit the rotational motion generated in the exterior 11-1 of the chamber 11 to the interior 11-2 of the chamber 11. Accordingly, the rotational motion about the first axis AX1, which is generated by the rotational portion 153, may be transmitted to the mask holder 151 through the sealing portion 152, and the mask holder 151 may rotate about the first axis AX1. Through the rotational motion about the first axis AX1 of the mask holder 151, the section of the first mask holding unit 15 may be converted to the states respectively shown in FIGS. 4A and 4B.

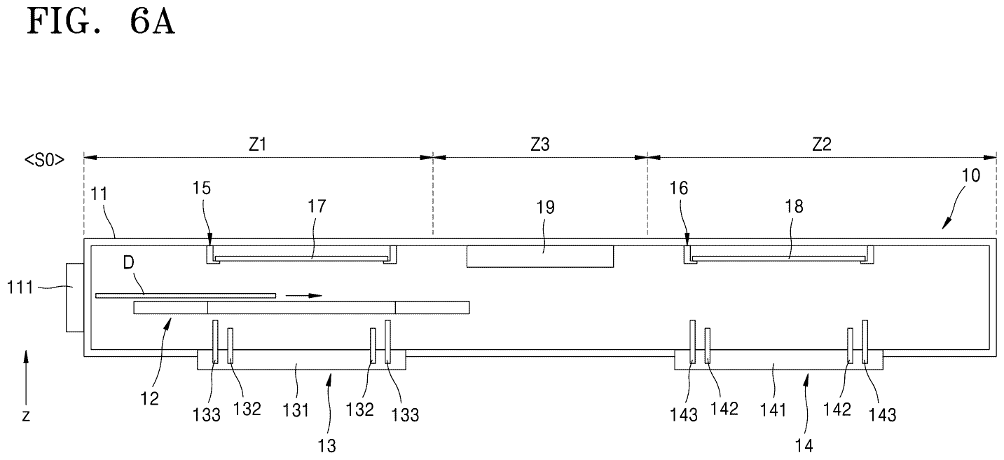

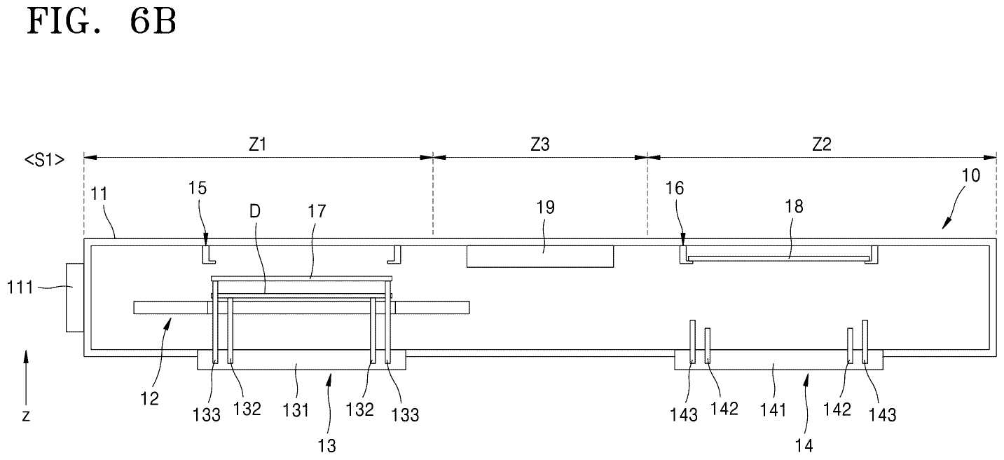

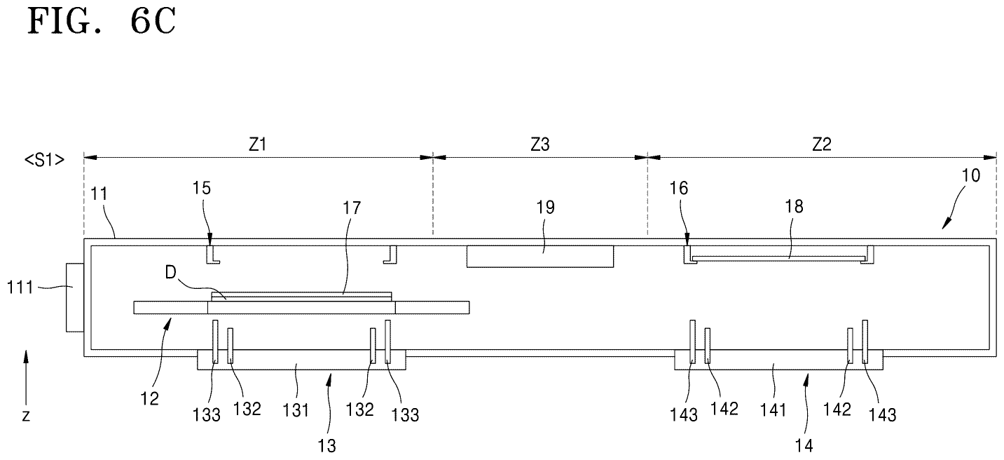

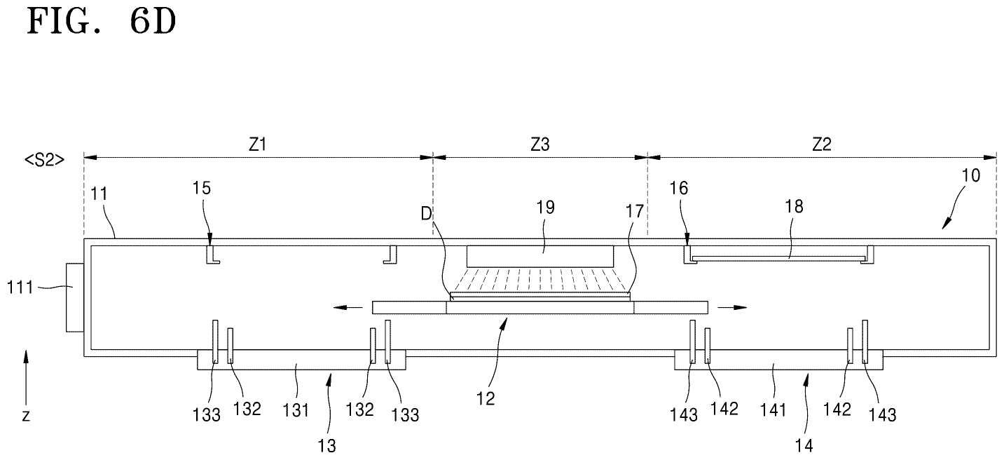

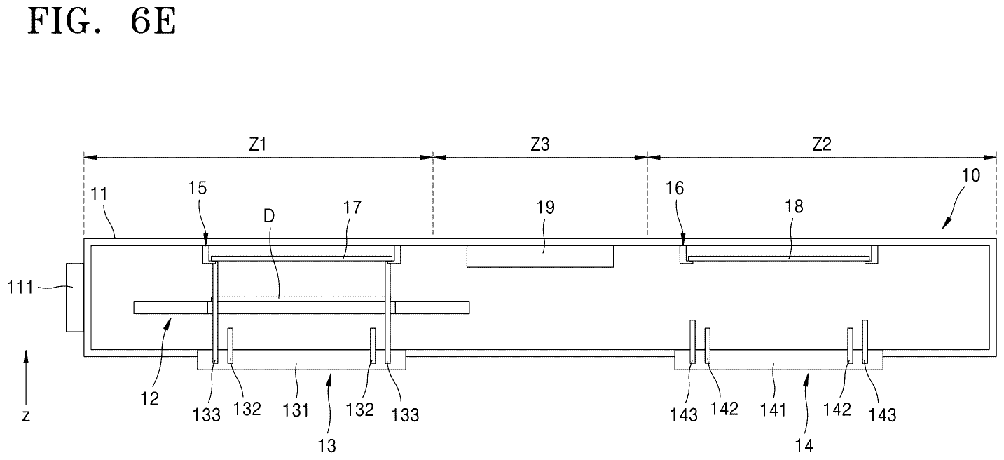

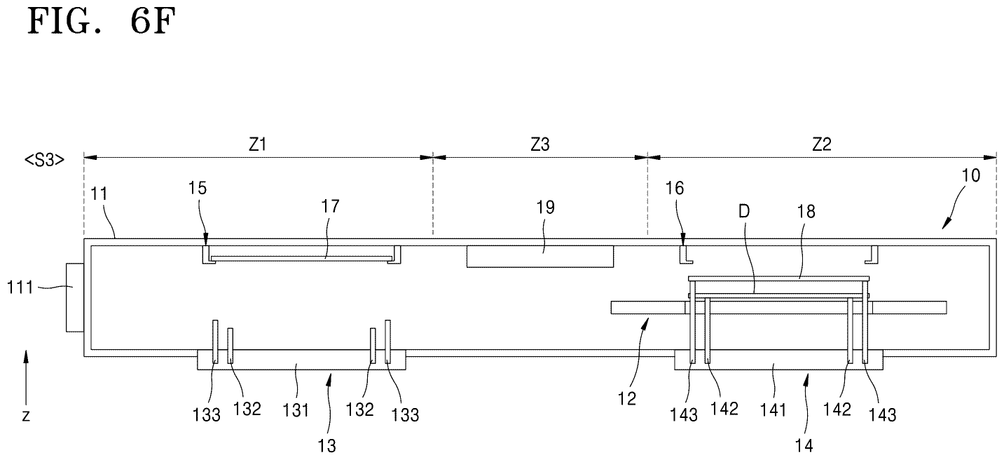

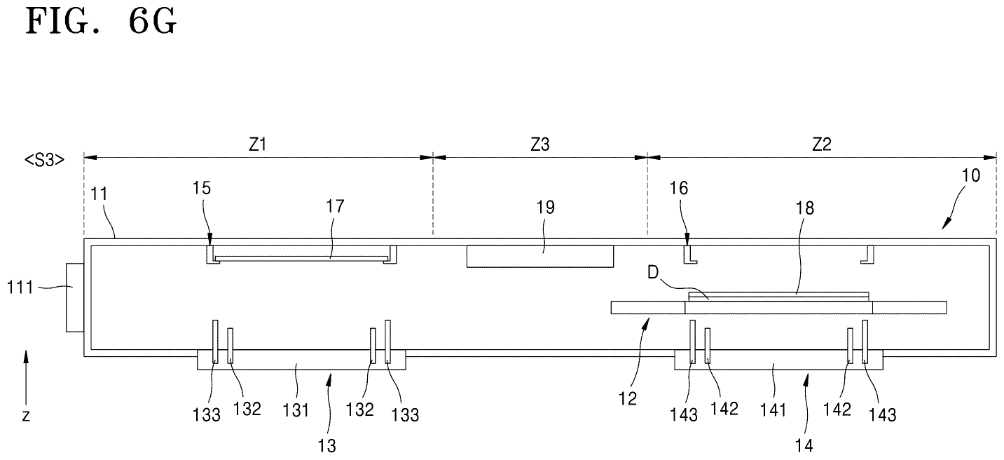

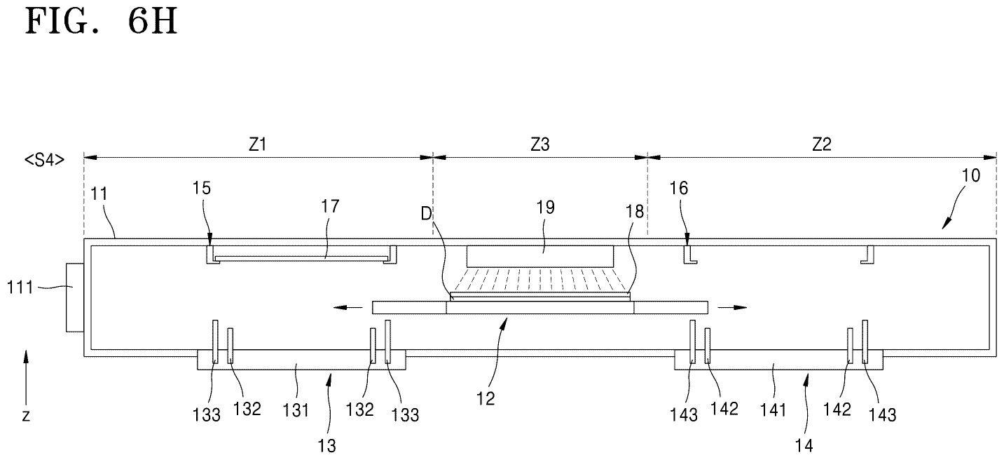

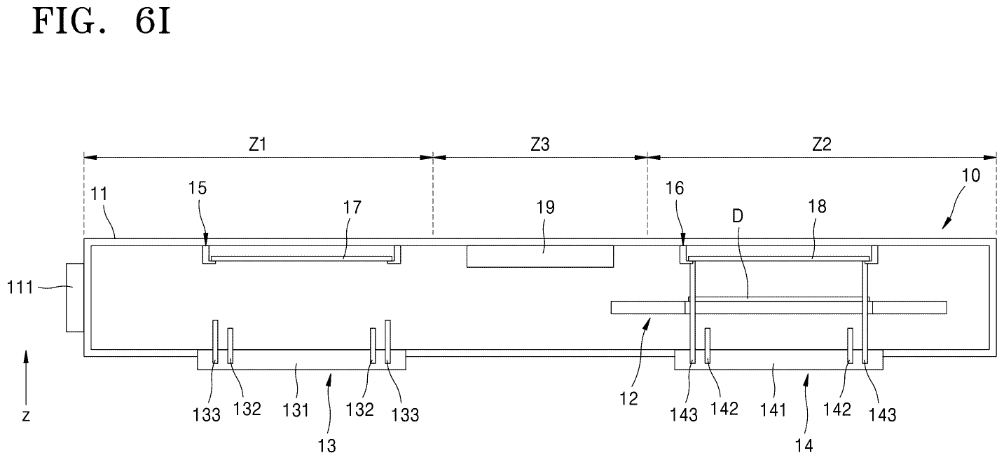

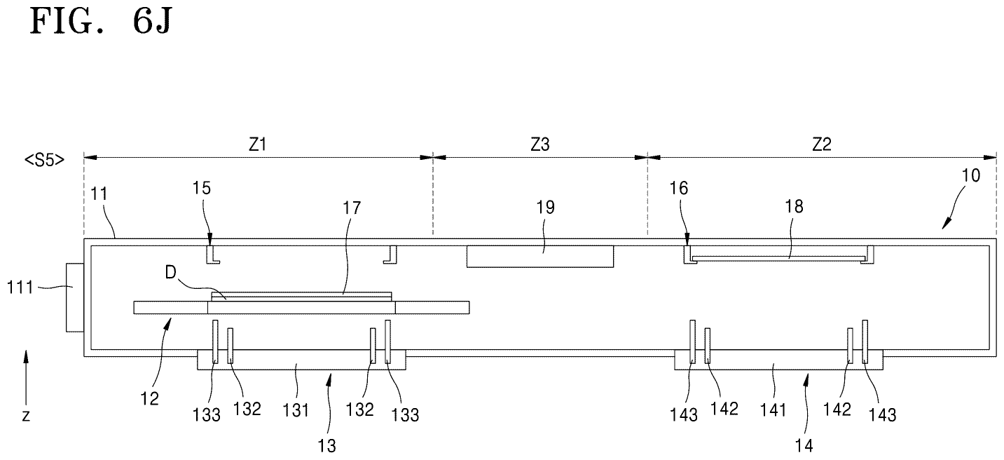

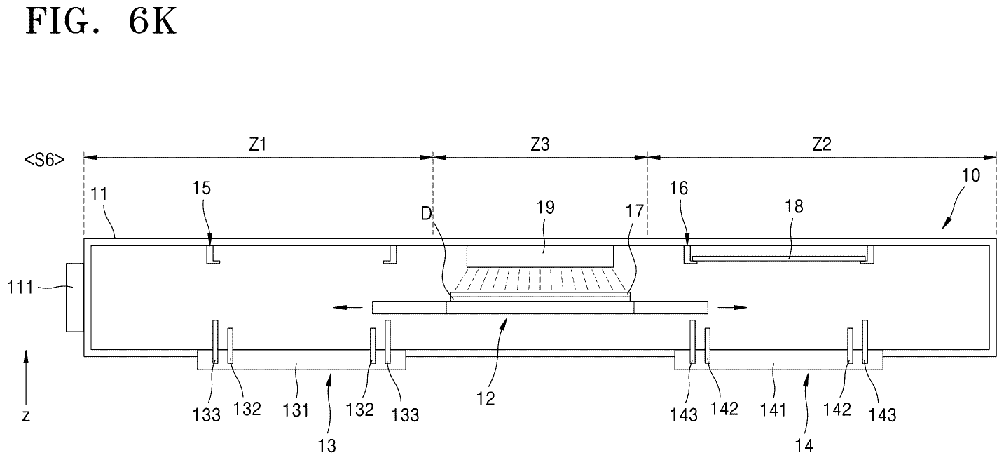

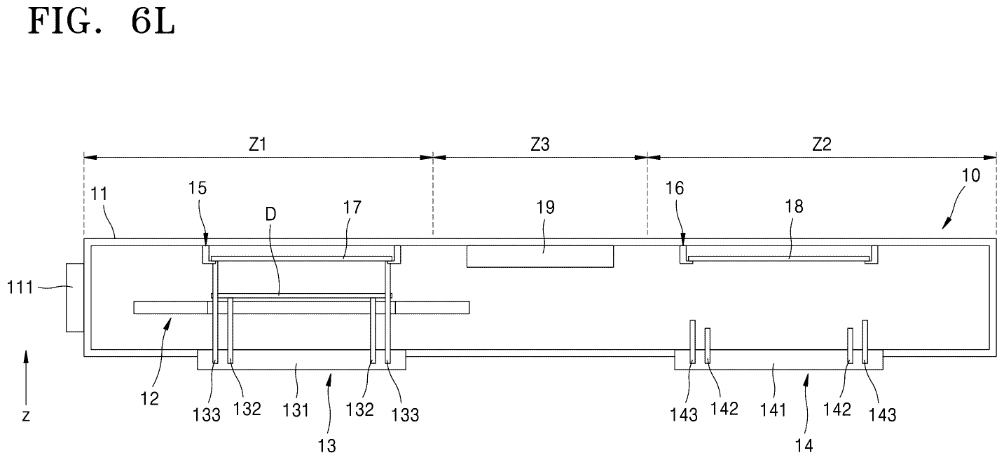

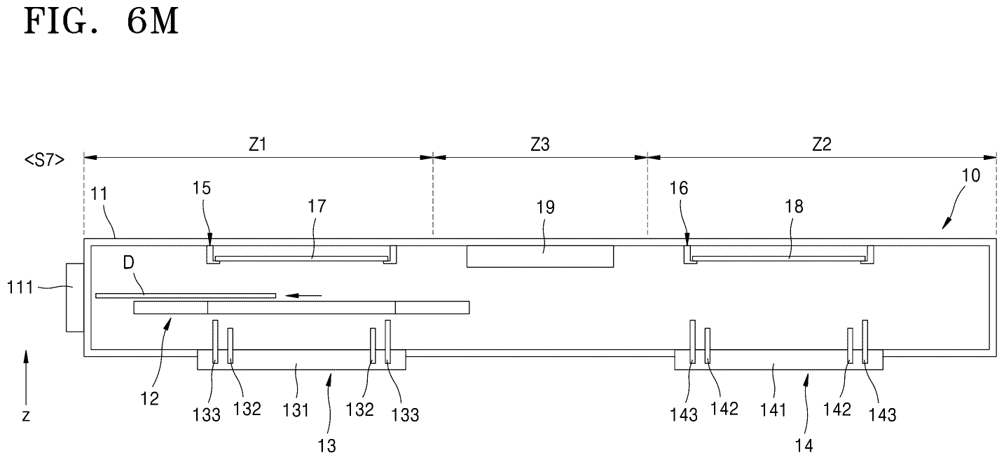

FIGS. 6A to 6M are cross-sectional views of an embodiment of processes of a method of manufacturing a display apparatus.

Referring to FIG. 6A, in a zeroth operation SO, the display substrate D may be inserted into the chamber 11. In an embodiment, the gate valve 111 may be opened, and the display substrate D may be inserted into the chamber 11 through a separate member (e.g., a robot arm) that moves the display substrate D. In an embodiment, the moving unit 12 may be disposed in the first zone Z1, and the display substrate D may be disposed in the first zone Z1 after being inserted into the chamber 11. In an embodiment, after the display substrate D is inserted into the chamber 11, the gate valve 111 may be closed. In an embodiment, the first and second deposition masks 17 and 18 may be held by the first and second mask holding units 15 and 16, respectively.

Referring to FIGS. 6B and 6C, in a first operation S1, the first deposition mask 17 and the display substrate D may be aligned and combined with each other.

Referring to FIG. 6B, after the moving unit 12 and the display substrate D are positioned in the first zone Z1, the first alignment unit 13 may operate to align the display substrate D and the first deposition mask 17 with each other. In an embodiment, the first mask moving portion 133 of the first alignment unit 13 may extend in the +z direction to pick up the first deposition mask 17, and the first substrate moving portion 132 of the first alignment unit 13 may extend in the +z direction to pick up the display substrate D. In an embodiment, the first aligner 131 may photograph alignment marks respectively provided on the display substrate D and the first deposition mask 17. In an embodiment, similar to the manner described above, the first mask moving portion 133 may adjust the position of the first deposition mask 17, and the first substrate moving portion 132 may adjust the position of the display substrate D, thereby aligning the first deposition mask 17 and the display substrate D with each other. In an embodiment, the alignment marks may serve as a standard for aligning the first deposition mask 17 and the display substrate D with each other.

Referring to FIG. 6C, the first deposition mask 17 and the display substrate D may be brought into proximity with each other. In an embodiment, after the first deposition mask 17 and the display substrate D are aligned with each other, the first substrate moving portion 132 may be shortened in a z direction to lower the display substrate D and place the display substrate D on the susceptor 121. In this case, the display substrate D may be in direct contact with a surface (e.g., an upper surface) of the susceptor 121. In an embodiment, the first mask moving portion 133 may be shortened in the z direction to lower the first deposition mask 17 and place the first deposition mask 17 on the display substrate D. In this case, the first deposition mask 17 may be in direct contact with a surface (e.g., an upper surface) of the display substrate D. In an embodiment, by a magnetic force portion (not shown) provided in the chamber 11, a magnetic force may be applied to the first deposition mask 17 in the −z direction to bring the first deposition mask 17 into greater proximity with the display substrate D. Accordingly, the first deposition mask 17 and the display substrate D may be combined with each other on the susceptor 121.

Thereafter, the first deposition mask 17 and the display substrate D may be moved to the third zone Z3 together with the moving unit 12. In other words, the moving unit 12, the first deposition mask 17, and the display substrate D may move to the third zone Z3 as one body.

Referring to FIG. 6D, in a second operation S2, an operation of depositing an inorganic film may be performed. In an embodiment, before deposition proceeds, the pressure in the chamber 11 may be set to a vacuum or a pressure similar to a vacuum by a pressure regulator (not shown) provided in the device 10 for manufacturing a display apparatus. In an embodiment, chemical vapor deposition (CVD) may be used in the second operation S2. In this case, the deposition unit 19 may operate to diffuse a deposition material in a gas state or a vapor state toward the first deposition mask 17 and the display substrate D. In an embodiment, the deposition material may include an inorganic material. Thereafter, or substantially at the same time, the susceptor 121 may be heated by a heat source provided in the susceptor 121, and the display substrate D in contact with the susceptor 121 may also be heated. In this case, a portion of a surface of the display substrate D, which overlaps the first opening 17-1 (refer to FIG. 4A) of the first deposition mask 17, may contact the deposition material. The deposition material may cause a chemical reaction with or on the surface of the display substrate D that has been heated, and a film may be formed on the display substrate D. In an embodiment, the film may be a first inorganic film. In this regard, the first deposition mask 17 may provide a deposition area, which is the same as or similar to a predetermined deposition area, through the first opening 17-1 (refer to FIG. 4A). In an embodiment, to form the first inorganic film to be thicker, while the deposition material continues to diffuse in the deposition unit 19, the moving unit 12 along with the first deposition mask 17 and the display substrate D, which are combined with each other on the moving unit 12, may be reciprocated in two directions (e.g., to the left and right).

Thereafter, the first deposition mask 17 and the display substrate D may be moved to the first zone Z1 together with the moving unit 12. In other words, the moving unit 12, the first deposition mask 17, and the display substrate D may move to the first zone Z1 as one body. In this regard, the first inorganic film may be formed on the display substrate D.

Referring to FIG. 6E, the first deposition mask 17 may be separated from the display substrate D. In an embodiment, the first mask moving portion 133 of the first alignment unit 13 may operate to separate the first deposition mask 17 from the display substrate D. In an embodiment, while the display substrate D is maintained on the susceptor 121, the first mask moving portion 133 may be extended to move the first deposition mask 17 in the +z direction, for example. In an embodiment, the first mask moving portion 133 may be further extended to dispose (e.g., seat) the first deposition mask 17 on the first mask holding unit 15. The process of disposing (e.g., seating) the first deposition mask 17 on the first mask holding unit 15 is the same as described above with reference to FIGS. 4A, 4B, and 5. Thereafter, the first mask moving portion 133 may be shortened in the z direction to return to the original position.

Thereafter, the display substrate D may be moved to the second zone Z2 together with the moving unit 12. In other words, the moving unit 12 and the display substrate D may move to the second zone Z2 as one body. In this regard, the first inorganic film may be formed on the display substrate D.

Referring to FIGS. 6F and 6G, in a third operation S3, the second deposition mask 18 and the display substrate D may be aligned and combined with each other.

Referring to FIG. 6F, after the moving unit 12 and the display substrate D are positioned in the second zone Z2, the second alignment unit 14 may operate to align the display substrate D and the second deposition mask 18 with each other. In an embodiment, the second mask moving portion 143 of the second alignment unit 14 may extend in the +z direction to pick up the second deposition mask 18, and the second substrate moving portion 142 of the second alignment unit 14 may extend in the +z direction to pick up the display substrate D. In an embodiment, the second aligner 141 may photograph alignment marks respectively provided on the display substrate D and the second deposition mask 18. In an embodiment, similar to the manner described above, the second mask moving portion 143 may adjust the position of the second deposition mask 18, and the second substrate moving portion 142 may adjust the position of the display substrate D, thereby aligning the second deposition mask 18 and the display substrate D with each other. In an embodiment, the alignment marks may serve as a standard for aligning the second deposition mask 18 and the display substrate D with each other.

Referring to FIG. 6G, the second deposition mask 18 and the display substrate D may be brought into proximity with each other. In an embodiment, after the second deposition mask 18 and the display substrate D are aligned with each other, the second substrate moving portion 142 may be shortened in the z direction to lower the display substrate D and further place the display substrate D on the susceptor 121. In this case, the display substrate D may be in direct contact with a surface (e.g., an upper surface) of the susceptor 121. In an embodiment, the second mask moving portion 143 may be shortened in the z direction to lower the second deposition mask 18 and further place the second deposition mask 18 on the display substrate D. In this case, the second deposition mask 18 may be in direct contact with a surface (e.g., an upper surface) of the display substrate D. In an embodiment, by a magnetic force portion (not shown) provided in the chamber 11, a magnetic force may be applied to the second deposition mask 18 in the −z direction to bring the second deposition mask 18 into greater proximity with the display substrate D. Accordingly, the second deposition mask 18 and the display substrate D may be combined with each other on the susceptor 121.

Thereafter, the second deposition mask 18 and the display substrate D may be moved to the third zone Z3 together with the moving unit 12. In other words, the moving unit 12, the second deposition mask 18, and the display substrate D may move to the third zone Z3 as one body. In this regard, the first inorganic film may be formed on the display substrate D.

Referring to FIG. 6H, in a fourth operation S4, an operation of depositing an organic film may be performed. In an embodiment, before deposition proceeds, the pressure in the chamber 11 may be set to a vacuum or a pressure similar to a vacuum by a pressure regulator (not shown) provided in the device 10 for manufacturing a display apparatus. In an embodiment, CVD may be used in the fourth operation S4. In this case, the deposition unit 19 may operate to diffuse a deposition material in a gas state or a vapor state toward the second deposition mask 18 and the display substrate D. In an embodiment, the deposition material may include an organic material. Thereafter, or substantially at the same time, the susceptor 121 may be heated by a heat source provided in the susceptor 121, and the display substrate D in contact with the susceptor 121 may also be heated. In this case, a portion of a surface of the display substrate D, which overlaps the second opening 18-1 (refer to FIG. 4A) of the second deposition mask 18, may contact the deposition material. The deposition material may cause a chemical reaction with or on the surface of the display substrate D that has been heated, and a film may be formed on the display substrate D. In an embodiment, the film may be a first organic film. In an embodiment, the first organic film may be formed on the first inorganic film. In this regard, the second deposition mask 18 may provide a deposition area, which is the same as or similar to a predetermined deposition area, through the second opening 18-1 (refer to FIG. 4A). In an embodiment, to form the first organic film to be thicker, while the deposition material continues to diffuse in the deposition unit 19, the moving unit 12 along with the second deposition mask 18 and the display substrate D, which are combined with each other on the moving unit 12, may be reciprocated in two directions (e.g., to the left and right).

Thereafter, the second deposition mask 18 and the display substrate D may be moved to the second zone Z2 together with the moving unit 12. In other words, the moving unit 12, the second deposition mask 18, and the display substrate D may move to the second zone Z2 as one body. In this regard, the first inorganic film and the first organic film may be formed on the display substrate D.

Referring to FIG. 6I, the second deposition mask 18 may be separated from the display substrate D. In an embodiment, the second mask moving portion 143 of the second alignment unit 14 may operate to separate the second deposition mask 18 from the display substrate D. In an embodiment, while the display substrate D is maintained on the susceptor 121, the second mask moving portion 143 may be extended to move the second deposition mask 18 in the +z direction, for example. In an embodiment, the second mask moving portion 143 may be further extended to dispose (e.g., seat) the second deposition mask 18 on the second mask holding unit 16. The process of disposing (e.g., seating) the second deposition mask 18 on the second mask holding unit 16 is the same as described above with reference to FIGS. 4A, 4B, and 5. Thereafter, the second mask moving portion 143 may be shortened in the z direction to return to the original position.

Thereafter, the display substrate D may be moved back to the first zone Z1 together with the moving unit 12. In other words, the moving unit 12 and the display substrate D may move to the first zone Z1 as one body. In this regard, the first inorganic film and the first organic film may be formed on the display substrate D.

Referring to FIG. 6J, in a fifth operation S5, the first deposition mask 17 and the display substrate D may be aligned and combined with each other. The process of aligning and combining the first deposition mask 17 and the display substrate D with each other may be substantially the same as described above with reference to FIGS. 6B and 6C. In this regard, the first inorganic film and the first organic film may be formed on the display substrate D.

Thereafter, the first deposition mask 17 and the display substrate D may be moved to the third zone Z3 together with the moving unit 12. In other words, the moving unit 12, the first deposition mask 17, and the display substrate D may move to the third zone Z3 as one body. In this regard, the first inorganic film and the first organic film may be formed on the display substrate D.

Referring to FIG. 6K, in a sixth operation S6, an operation of depositing an inorganic film may be performed. The operation of forming the inorganic film may be substantially the same as described above with reference to FIG. 6D. In this regard, the first inorganic film and the first organic film may be formed on the display substrate D. A second inorganic film may be formed on the first organic film through the sixth operation S6.

Thereafter, the first deposition mask 17 and the display substrate D may be moved to the first zone Z1 together with the moving unit 12. In other words, the moving unit 12, the first deposition mask 17, and the display substrate D may move to the first zone Z1 as one body. In this regard, the first inorganic film, the first organic film, and the second inorganic film may be formed on the display substrate D.

Referring to FIG. 6L, the first deposition mask 17 may be separated from the display substrate D. The process of separating the first deposition mask 17 from the display substrate D may be substantially the same as described above with reference to FIG. 6E.

Referring to FIG. 6M, in a seventh operation S7, the display substrate D may be taken out of the chamber 11. In an embodiment, the gate valve 111 may be opened, and the display substrate D may be taken out of the chamber 11 through a separate member (e.g., a robot arm) that moves the display substrate D. In this regard, the first inorganic film, the first organic film, and the second inorganic film may be sequentially arranged on the display substrate D.

FIGS. 6A to 6M illustrate a process of forming two inorganic films and one organic film, but the disclosure is not limited thereto. In another embodiment, some of the above-described processes may be repeatedly performed to form M inorganic films (where M is a natural number of 1 or more) and/or N organic films (where N is a natural number of 1 or more).

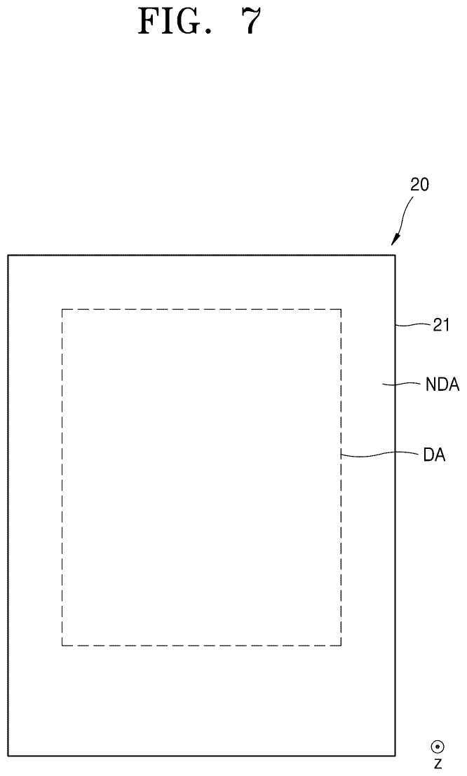

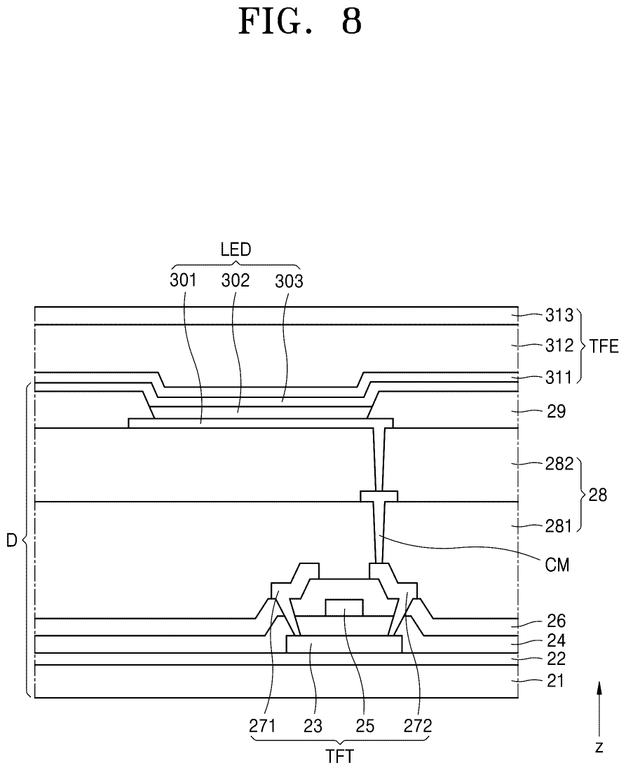

FIG. 7 is a plan view of an embodiment of a display apparatus 20 manufactured by the device 10 for manufacturing a display apparatus. FIG. 8 is a cross-sectional view of an embodiment of a portion of the display apparatus 20 manufactured by the device 10 for manufacturing a display apparatus.

Referring to FIGS. 7 and 8, the display apparatus 20 may include a display area DA and a non-display area NDA outside the display area DA, which are defined on a substrate 21. A light-emitting device LED may be disposed in the display area DA, and a power wiring (not shown) may be disposed in the non-display area NDA. In addition, a pad portion (not shown) may be disposed in the non-display area NDA. A plurality of deposition material patterns may be arranged in the display area DA.

The display apparatus 20 may include the display substrate D and a thin-film encapsulation layer TFE disposed on the display substrate D. The display substrate D may include the substrate 21, a thin-film transistor TFT, a via layer 28, and the light-emitting device LED.

The substrate 21 may include or consist of a plastic material or a metal material. In addition, the substrate 21 may include or consist of polyimide. The thin-film transistor TFT may be disposed on the substrate 21, the via layer 28 may be disposed to cover the thin-film transistor TFT, and the light-emitting device LED may be disposed on the via layer 28.

A buffer layer 22 including or consisting of an organic compound and/or an inorganic compound may be further disposed on an upper surface of the substrate 21, and the buffer layer 22 may include or consist of SiOₓ (where x≥1) and/or SiNₓ (where x ≥1).

After an active layer 23 disposed in a predetermined pattern is disposed on the buffer layer 22, the active layer 23 may be buried by a gate insulating layer 24. The active layer 23 may have a source region and a drain region and may further include a channel region therebetween. The active layer 23 may be formed to include or consist of various materials. In an embodiment, the active layer 23 may include or consist of an inorganic semiconductor material such as amorphous silicon or crystalline silicon. In another embodiment, the active layer 23 may include or consist of an oxide semiconductor. In another embodiment, the active layer 23 may include or consist of an organic semiconductor material. However, for convenience of description, hereinafter, a case in which the active layer 23 includes or consists of amorphous silicon is mainly described in detail.

The active layer 23 may be formed by forming an amorphous silicon film on the buffer layer 22, crystallizing the amorphous silicon film to form a polycrystalline silicon film, and patterning the polycrystalline silicon film. The source region and the drain region of the active layer 23 may be doped with impurities depending on the type of a thin-film transistor, such as a driving thin-film transistor or a switching thin-film transistor.

A gate electrode 25 corresponding to the active layer 23 and an inter-insulating layer 26 that buries the gate electrode 25 may be disposed on an upper surface of the gate insulating layer 24. After contact holes are defined in the inter-insulating layer 26 and the gate insulating layer 24, a source electrode 271 and a drain electrode 272 may be arranged on the inter-insulating layer 26 to contact the source region and the drain region of the active layer 23, respectively.

The via layer 28 may be disposed on the thin-film transistor TFT, and a pixel electrode 301 of the light-emitting device LED may be arranged on the via layer 28. The via layer 28 may include a first via layer 281 that buries the source electrode 271 and the drain electrode 272, and a second via layer 282 on the first via layer 281. The via layer 28, e.g., the first and second via layers 281 and 282, may include or consist of an inorganic material and/or an organic material. The via layer 28 may be formed as a planarization film, so that an upper surface thereof is flat regardless of the curvature of a film therebelow, or may be curved along the curvature of a film therebelow.

A via hole may be defined in the first via layer 281, and at least a portion of a contact metal CM may be disposed in the via hole of the first via layer 281. A via hole may also be defined in the second via layer 282, and a portion of the pixel electrode 301 may be disposed in the via hole of the second via layer 282. The pixel electrode 301 may contact the drain electrode 272 of the thin-film transistor TFT through a via hole defined in the via layer 28. In an embodiment, the contact metal CM may contact the drain electrode 272 through the via hole defined in the first via layer 281, and the pixel electrode 301 may contact the contact metal CM through the via hole defined in the second via layer 282, so that the pixel electrode 301 is connected to the drain electrode 272, for example.

After the pixel electrode 301 is disposed on the via layer 28, a pixel defining film 29 may include or consist of an organic material and/or an inorganic material to cover the pixel electrode 301 and the via layer 28 and may be opened to expose a portion of the pixel electrode 301.

An intermediate layer 302 and an opposite electrode 303 may be arranged on the pixel electrode 301. In an embodiment, the opposite electrode 303 may be disposed on the intermediate layer 302 and the pixel defining film 29. The pixel electrode 301 may function as an anode, and the opposite electrode 303 may function as a cathode. However, the polarities of the pixel electrode 301 and the opposite electrode 303 may be reversed. The pixel electrode 301 and the opposite electrode 303 may be insulated from each other by the intermediate layer 302 and may apply voltages of different polarities to the intermediate layer 302 to allow light to be emitted from an organic emission layer.

The intermediate layer 302 may include an organic emission layer. In another optional example, the intermediate layer 302 may include an organic emission layer and may further include at least one of a hole injection layer, a hole transport layer, an electron transport layer, and an electron injection layer. The illustrated embodiment is not limited thereto, and the intermediate layer 302 may include an organic emission layer and may further include various other functional layers (not shown).

One unit pixel may be made up of a plurality of subpixels, and the plurality of subpixels may emit light of various colors. In an embodiment, the plurality of subpixels may include subpixels emitting red light, green light, and blue light, respectively, and may include subpixels (not shown) emitting red light, green light, blue light, and white light, respectively, for example. A subpixel as described above may include one intermediate layer 302.

The thin-film encapsulation layer TFE may be disposed to cover the light-emitting device LED. The thin-film encapsulation layer TFE may include a plurality of inorganic layers or may include an inorganic layer and an organic layer. The inorganic layer of the thin-film encapsulation layer TFE may be a single film or a stacked film including metal oxide or metal nitride. In an embodiment, the inorganic layer may include any one of SiNₓ, Al₂O₃, SiO₂, and TiO₂, for example. The organic layer of the thin-film encapsulation layer TFE may include or consist of a polymer and may be, e.g., a single film or a stacked film including or consisting of any one of polyethylene terephthalate, polyimide, polycarbonate, epoxy, polyethylene, and polyacrylate. In an embodiment, an uppermost layer of the thin-film encapsulation layer TFE, which is exposed to the outside, may be formed as an inorganic layer to prevent moisture from penetrating into the light-emitting device LED.

The thin-film encapsulation layer TFE may be formed by the device 10 for manufacturing a display apparatus, described above. In an embodiment, the thin-film encapsulation layer TFE may include a first inorganic encapsulation layer 311 covering the opposite electrode 303, an organic encapsulation layer 312 on the first inorganic encapsulation layer 311, and a second inorganic encapsulation layer 313 on the organic encapsulation layer 312, for example. In this case, the first inorganic film, the first organic film, and the second inorganic film described above with reference to FIGS. 6A to 6M may correspond to the first inorganic encapsulation layer 311, the organic encapsulation layer 312, and the second inorganic encapsulation layer 313, respectively.

According to the embodiments, a device and method for manufacturing a display apparatus, where an inorganic film and an organic film of a thin-film encapsulation layer may be formed in one chamber, may be provided.

Accordingly, because there is no need to separately provide a chamber for forming an inorganic film and a chamber for forming an organic film, the number of facilities and resulting costs may be reduced.

In addition, because an inorganic film and an organic film may be formed in a single chamber without the need to move a substrate between a chamber for forming an inorganic film and a chamber for forming an organic film, a manufacturing time may also be shortened.

It should be understood that embodiments described herein should be considered in a descriptive sense only and not for purposes of limitation. Descriptions of features or advantages within each embodiment should typically be considered as available for other similar features or advantages in other embodiments. While embodiments have been described with reference to the drawing figures, it will be understood by those of ordinary skill in the art that various changes in form and details may be made therein without departing from the spirit and scope as defined by the following claims.

What is claimed is:

1. A device for manufacturing a display apparatus, the device comprising:
a chamber comprising a first zone, a second zone, and a third zone arranged along a linear path;
an inorganic film deposition mask disposed in the first zone;
an organic film deposition mask disposed in the second zone;
a deposition unit disposed in the third zone; and
a susceptor which reciprocates between the first zone, the second zone, and the third zone.

2. The device of claim 1, wherein the third zone is disposed between the first zone and the second zone.

3. The device of claim 1, further comprising:
a first alignment unit disposed in the first zone; and
a second alignment unit disposed in the second zone.

4. The device of claim 3, wherein at least one of the first alignment unit and the second alignment unit comprises:
a mask moving portion which raises and lowers a mask; and
a substrate moving portion which raises and lowers a substrate.

5. The device of claim 4, wherein the mask moving portion and the substrate moving portion are extended and shortened in a predetermined direction.

6. The device of claim 3, further comprising:
a first mask holding unit which is disposed in the first zone and faces the first alignment unit; and
a second mask holding unit which is disposed in the second zone and faces the second alignment unit.

7. The device of claim 6, wherein at least one of the first mask holding unit and the second mask holding unit comprises a plurality of mask holders which bend and rotate.

8. The device of claim 6, wherein the deposition unit and at least one of the first mask holding unit and the second mask holding unit are arranged on a same surface of the chamber.

9. The device of claim 1, wherein a first opening is defined in the inorganic film deposition mask,
a second opening is defined in the organic film deposition mask, and
the first opening and the second opening respectively have sizes different from each other.

10. The device of claim 1, further comprising a buffer plate attached to at least one of opposite sides of the susceptor.

11. A method of manufacturing a display apparatus, the method comprising:
combining a substrate and an inorganic film deposition mask with each other on a susceptor in a first zone of a chamber;
depositing a first inorganic film on the substrate by a deposition unit and the inorganic film deposition mask in a third zone of the chamber;
combining the substrate and an organic film deposition mask with each other on the susceptor in a second zone of the chamber; and
depositing an organic film on the first inorganic film by the deposition unit and the organic film deposition mask in the third zone of the chamber.

12. The method of claim 11, wherein the combining the substrate and the inorganic film deposition mask comprises at least one of:
bringing the inorganic film deposition mask into proximity with the substrate; and
aligning the substrate and the inorganic film deposition mask with each other.

13. The method of claim 11, wherein the combining the substrate and the organic film deposition mask comprises at least one of:
bringing the organic film deposition mask into proximity with the substrate; and
aligning the substrate and the organic film deposition mask with each other.

14. The method of claim 11, further comprising at least one of:
moving the susceptor, the substrate, and the inorganic film deposition mask from the first zone to the third zone as one body; and
moving the susceptor, the substrate, and the organic film deposition mask from the second zone to the third zone as one body.

15. The method of claim 11, further comprising at least one of:
separating the inorganic film deposition mask from the substrate; and
separating the organic film deposition mask from the substrate.

16. The method of claim 15, further comprising at least one of:
holding the inorganic film deposition mask on a first mask holding unit provided on one surface of the chamber; and
holding the organic film deposition mask on a second mask holding unit provided on the one surface of the chamber.

17. The method of claim 16, wherein the deposition unit and at least one of the first mask holding unit and the second mask holding unit are arranged on a same surface of the chamber.

18. The method of claim 11, further comprising:
recombining the substrate and the inorganic film deposition mask with each other on the susceptor in the first zone of the chamber; and
depositing a second inorganic film on the organic film by the deposition unit and the inorganic film deposition mask in the third zone of the chamber.

19. The method of claim 11, further comprising inserting the substrate into the chamber.

20. The method of claim 11, wherein the third zone is disposed between the first zone and the second zone.
